(19) United States
(12) Patent Application Publication
(10) Pub. No.: US 2024/0395458 A1
(43) Pub. Date: Nov. 28, 2024

(54) CAPACITOR AND METHOD OF MANUFACTURING CAPACITOR

(71) Applicant: KABUSHIKI KAISHA TOSHIBA, Tokyo (JP)

(72) Inventors: Susumu OBATA, Yokohama (JP); Kazuhito HIGUCHI, Yokohama (JP); Takayuki TAJIMA, Sagamihara (JP); Mitsuo SANO, Kamakura (JP)

(73) Assignee: KABUSHIKI KAISHA TOSHIBA, Tokyo (JP)

(21) Appl. No.: 18/603,302

(22) Filed: Mar. 13, 2024

(30) Foreign Application Priority Data
May 26, 2023 (JP) 2023-087032

(51) Int. Cl. H01G 4/005

(52) U.S. Cl. CPC H01G 4/005

(57) ABSTRACT

According to one embodiment, a capacitor includes a substrate having a first main surface and a second main surface is provided. The capacitor includes at least one first recess provided on the first main surface of the substrate along one direction, and at least one second recess provided on the second main surface of the substrate along said one direction. In the substrate, the at least one first recess and the at least one second recess are alternately aligned along said one direction.

### CROSS-REFERENCE TO RELATED APPLICATION(S)

This application is based upon and claims the benefit of priority from Japanese Patent Application No. 2023-087032, filed May 26, 2023, the entire contents of which are incorporated herein by reference.

### FIELD

Embodiments described herein relate generally to a capacitor and a method of manufacturing a capacitor.

### BACKGROUND

With the downsizing and upgrading of communication devices, capacitors mounted thereon are desired to be smaller and thinner. A trench capacitor having a substrate with trenches extending therein for the purpose of surface area enhancement is known as a structure for achieving a smaller and thinner capacitor while maintaining the capacitance density. Such a trench capacitor has a problem wherein a defect, such as warpage of its substrate, occurs during the manufacturing process.

### BRIEF DESCRIPTION OF THE DRAWINGS

FIG. 1 is a perspective view schematically showing a capacitor according to a first embodiment.

FIG. 2 is a top view of the capacitor shown in FIG. 1.

FIG. 3 is a sectional view of the capacitor shown in FIG. 2, along line III-III.

FIG. 4 is a flowchart showing an example of a manufacturing method of the capacitor according to the first embodiment.

FIG. 5 is a sectional view showing an example of step S1 of the method shown in FIG. 4.

FIG. 6 is a sectional view showing an example of step S2 of the method shown in FIG. 4.

FIG. 7 is a sectional view showing an example of step S3 of the method shown in FIG. 4.

FIG. 8 is a sectional view showing an example of step S4 of the method shown in FIG. 4.

FIG. 9 is a sectional view showing an example of step S5 of the method shown in FIG. 4.

FIG. 10 is a sectional view showing an example of step S6 of the method shown in FIG. 4.

FIG. 11 is a sectional view showing an example of step S7 of the method shown in FIG. 4.

FIG. 12 is a sectional view showing an example of step S8 of the method shown in FIG. 4.

FIG. 13 is a sectional view showing an example of step S9 of the method shown in FIG. 4.

FIG. 14 is a sectional view showing an example of step S10 of the method shown in FIG. 4.

FIG. 15 is a sectional view showing an example of step S12 of the method shown in FIG. 4.

FIG. 16 is a sectional view schematically showing a capacitor according to a second embodiment.

FIG. 17 is a flowchart showing an example of a manufacturing method of the capacitor according to the second embodiment.

FIG. 18 is a sectional view schematically showing a capacitor according to a third embodiment.

FIG. 19 is a flowchart showing an example of a manufacturing method of the capacitor according to the third embodiment.

FIG. 20 is a sectional view schematically showing a capacitor of a comparative example.

### DETAILED DESCRIPTION

In general, according to one embodiment, a capacitor including a substrate having a first main surface and a second main surface, at least one first recess provided on the first main surface of the substrate along one direction, and at least one second recess provided on the second main surface of the substrate along said one direction is provided. In the substrate, at least one first recess and at least one second recess are alternately aligned along said one direction.

According to another embodiment, a method of manufacturing a capacitor is provided. This manufacturing method is a method of manufacturing a capacitor provided by the foregoing embodiment, and includes forming at least one first recess and at least one second recess of a substrate in a batch by etching using a catalyst.

Embodiments will be described below in detail with reference to the drawings. Structural elements that exert the same or a similar function are referenced by the same number throughout the drawings and duplicate descriptions are omitted.

### First Embodiment

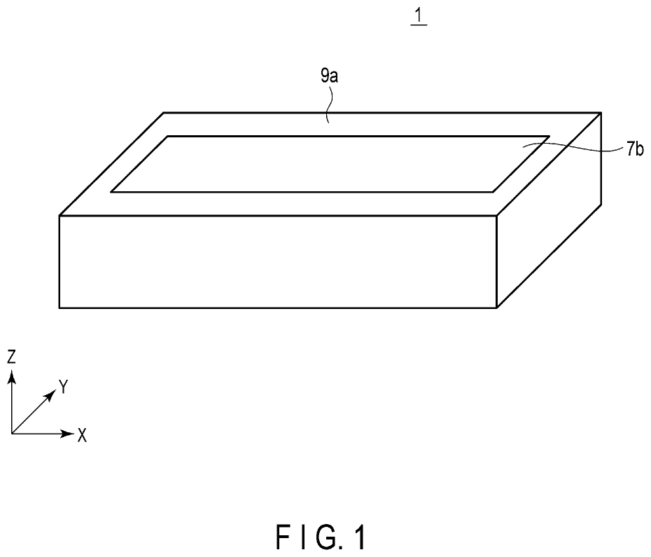

A capacitor of the first embodiment and a method of manufacturing the capacitor are shown in FIGS. 1 through 15.

The capacitor 1 includes a substrate 2, a first dielectric layer 3a, a second dielectric layer 3b, a first conductive layer 4a, a second conductive layer 4b, a first electrode 7, a second electrode 8, and insulating layers 9a and 9b, as shown in FIGS. 1 through 3.

In each drawing, an X-axis direction is a first direction parallel to the main surface of the substrate 2, and a Y-axis direction is a second direction parallel to the main surface of the substrate 2 and perpendicular to the X-axis direction. A Z-axis direction is a thickness direction of the substrate 2, namely a direction perpendicular to the X-axis direction (first direction) and the Y-axis direction (second direction).

The substrate 2 is a substrate of which at least the surfaces have electrical conductivity. The substrate 2 has a first main surface A1, a second main surface A2, and edge surfaces extending from the edge of the first main surface A1 and the second main surface A2. Herein, the substrate 2 has a flat, approximately rectangular parallelepiped shape. The substrate 2 may have other shapes.

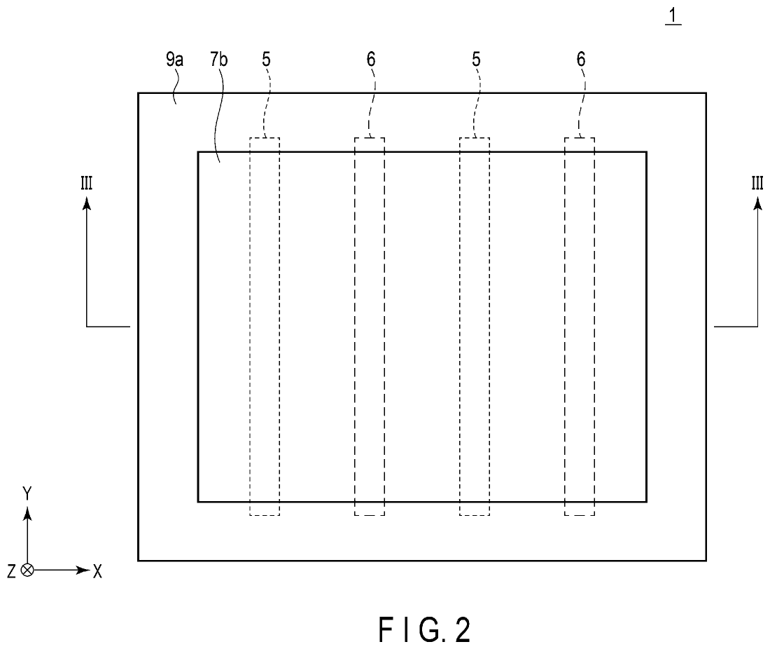

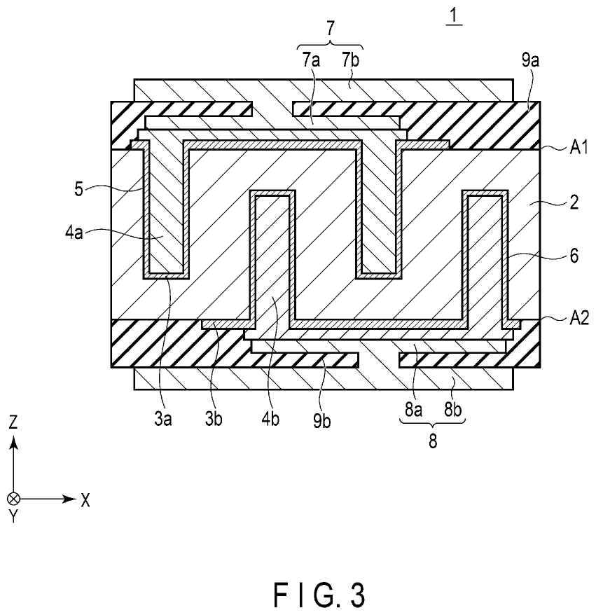

On the first main surface A1, a plurality of first recesses 5 shown in FIGS. 2 and 3 are provided. Herein, these first recesses 5 are first trenches each having a shape extending in the Y-axis direction, namely the second direction. The first recesses 5 are aligned along the X-axis direction (first direction), separated from one another by side walls, as shown in FIGS. 2 and 3. A cross-section of the first recess 5 has a closed rectangular cylindrical shape, when cut along the X-axis direction. In the first main surface A1, a plurality of first recesses 5 or only one first recess 5 may be provided.

On the second main surface A2, a plurality of second recesses 6 shown in FIGS. 2 and 3 are provided. Herein, these second recesses 6 are second trenches each having a shape extending in the Y-axis direction, namely the second direction. The second recesses 6 are aligned along the X-axis direction (first direction), separated from one another by side walls, as shown in FIGS. 2 and 3. The second recesses 6 are provided at positions on the second main surface A2 so as to face the side walls of the first recesses 5, not at the positions to face the bottom walls of the first recesses 5. In other words, the first recesses 5 and the second recesses 6 are alternately arranged along the X-axis direction (first direction) in the substrate 2, with the side walls interposed therebetween. In the second main surface A2, a plurality of second recesses 6 or only one second recess 6 may be provided.

The depth of the first recesses 5 and the depth of the second recesses 6 may depend on the thickness of the substrate 2 but are within the range from 0.1 μm to 500 μm according to one example, and within the range from 1 μm to 400 μm according to another example.

It is preferable that a dimension of the opening of each of the first recesses 5 and the second recesses 6 be 0.3 μm or more. Note that the dimension herein is a diameter or a width of each opening. The dimension herein is a dimension in a direction perpendicular to the length directions of the first recesses 5 and the second recesses 6. If these dimensions are reduced, a larger electric capacitance can be achieved. If these dimensions are reduced, however, it becomes difficult to form a stacked structure including dielectric layers and conductive layers in the first recesses 5 and the second recesses 6.

A distance between adjacent first recesses 5 and a distance between adjacent second recesses 6 are each preferably 0.1 μm or more. If these distances are reduced, a larger electric capacitance can be achieved. If these distances are reduced, however, a portion of the substrate 2 sandwiched between the first recesses 5 and a portion of the substrate 2 sandwiched between the second recesses 6 are likely to be damaged.

The first recesses 5 and the second recesses 6 can have various shapes. For example, in FIG. 3, the cross sections of the first recesses 5 and the second recesses 6 parallel to the depth direction thereof are rectangular. These cross sections are not necessarily rectangular. For example, these cross sections may have a tapered shape.

In FIGS. 2 and 3, the first recesses 5 and the second recesses 6 have a shape extending in the Y direction (second direction) and are arranged along the X-axis direction (first direction), spaced from one another by the side walls. The arrangement is not limited to this example; the first recesses 5 and the second recesses 6 may have a shape extending in the X-axis direction (first direction) and be arranged along the Y direction (second direction), spaced from one another by the side walls.

The substrate 2 is preferably a substrate containing silicon, such as a silicon substrate. Such a substrate can be processed using a semiconductor process. Examples of the substrate 2 include a monocrystalline silicon wafer. A plane direction of the monocrystalline silicon wafer is not limited to a specific one; a silicon wafer having a (100) plane or a (110) plane as one of the main surfaces can be used.

The first dielectric layer 3a and the second dielectric layer 3b are a layer conformal to the surfaces of the substrate 2. The first dielectric layer 3a electrically insulates the substrate 2 from the first conductive layer 4a. The first conductive layer 4a may be provided in at least the first recess 5. The first dielectric layer 3a may be interposed between the substrate 2 and the first conductive layer 4a. The second dielectric layer 3b electrically insulates the substrate 2 from the second conductive layer 4b. The second conductive layer 4b may be provided in at least the second recess 6. The second dielectric layer 3b may be interposed between the substrate 2 and the second conductive layer 4b.

In the case of FIG. 3, the first conductive layer 4a is provided inside each first recess 5. The first conductive layer 4a is provided on the first main surface A1 located between adjacent first recesses 5 between which the side wall is interposed in the X-axis direction (first direction). The first conductive layers 4a provided inside each of the first recesses 5 are electrically coupled to each other by the above arrangement of the first conductive layers 4a. The first conductive layer 4a is comb-shaped. The second conductive layer 4b is provided inside each of the second recesses 6. The second conductive layer 4b is provided on the second main surface A2 located between adjacent second recesses 6 with the side wall interposed therebetween in the X-axis direction (first direction). The second conductive layers 4b provided inside each of the second recesses 6 are electrically coupled to each other by the above arrangement of the second conductive layers 4b. The second conductive layer 4b is comb-shaped. The first and second conductive layers 4a and 4b are made of polysilicon doped with impurities in order to improve conductivity, or a metal or an alloy of molybdenum, aluminum, gold, tungsten, platinum, nickel, or copper. Examples of impurities are P-type impurities and N-type impurities. The first and second conductive layers 4a and 4b may have a single-layer structure or a multi-layer structure.

In the case of FIG. 3, the first dielectric layer 3a is provided on the inner surface of each first recess 5 and a part of the first main surface A1 and is interposed between the substrate 2 and the first conductive layer 4a. The second dielectric layer 3b is provided on the inner surface of each second recess 6 and a part of the second main surface A2 and is interposed between the substrate 2 and the second conductive layer 4b. The first dielectric layer 3a and the second dielectric layer 3b are made of an organic dielectric or an inorganic dielectric, for example. As an organic dielectric, polyimide can be used, for example. A ferroelectric may be used as an inorganic dielectric; however, examples of an inorganic dielectric are an oxide film and a nitride film. Paraelectrics, such as silicon nitride, silicon oxide, silicon oxynitride, titanium oxide, and tantalum oxide, are preferable. These paraelectrics have a small change in dielectric constant with temperature. Therefore, when the paraelectrics are used for the first and second dielectric layers 3a and 3b, the heat resistance of the capacitor 1 can be improved.

The capacitor 1 further includes a first electrode 7, a second electrode 8, and insulating layers 9a and 9b, which are all shown in FIG. 3.

The first electrode 7 includes a first lower electrode 7a electrically coupled to the first conductive layer 4a by being formed thereon, and a first external pad 7b electrically coupled to the first lower electrode 7a. The first electrode 7 can be obtained by deposition of a metal, such as aluminum, by sputtering, for example.

On the other hand, the second electrode 8 includes a second lower electrode 8a electrically coupled to the second conductive layer 4b by being formed thereon, and a second external pad 8b electrically coupled to the second lower electrode 8a. The second electrode 8 is obtained by deposition of a metal such as aluminum by, for example, sputtering.

The insulating layer 9a insulates the first external pad 7b from the first main surface A1. The insulating layer 9a has one or more through-holes. In one through-hole of the insulating layer 9a, the first lower electrode 7a is electrically coupled to the first conductive layer 4a. The insulating layer 9a covers the edges of the first conductive layer 4a and the first dielectric layer 3a, and the first main surface A1. The external pad 7b projects from the surface of the insulating layer 9a along the XY plane in the Z-axis direction (the thickness direction of the substrate 2). The insulating layer 9b insulates the second external pad 8b from the second main surface A2. The insulating layer 9b has one or more through-holes. In one through-hole of the insulating layer 9b, the second lower electrode 8a is electrically coupled to the second conductive layer 4b. The insulating layer 9b covers the edges of the second conductive layer 4b and the second dielectric layer 3b, and the second main surface A2. The external pad 8b projects from the surface of the insulating layer 9b in the XY plane in the Z direction (the thickness direction of the substrate 2) but in a direction opposite to the projection of the external pad 7b. The insulating layers 9a and 9b are made of an inter-layer insulating film, such as tetraethoxysilane (TEOS), for example.

This capacitor 1 may further include a plated layer (not shown). The plated layer may be made of nickel (Ni), aluminum (Al), or a NiAl alloy, for example. The plated layer may be arranged between the first conductive layer 4a and the first electrode 7 and/or between the second conductive layer 4b and the second electrode 8, for example.

A capacitor according to the first embodiment includes at least one first recess provided on the first main surface of the substrate along one direction and at least one second recess provided on the second main surface of the substrate along said one direction. In the substrate, at least one first recess and at least one second recess are alternately aligned along said one direction. According to a capacitor having this substrate, it is possible to reduce defects, such as warpage and cracks in the substrate, through processing the first main surface and the second main surface in a batch. For example, batch forming of first recesses on the first main surface and second recesses on the second main surface by etching using a catalyst can suppress occurrence of warpage in the substrate during the forming of the recesses. Furthermore, batch processing of the surfaces leads to a reduction in the number of steps. If polysilicon doped with impurities is used as a conductive layer, polysilicon having a lower resistance value tends to exhibit a larger stress, as described later. According to the first embodiment, even if a conductive layer exhibiting a low resistance rate and a large stress is used, in other words, regardless of the type of a conductive layer, it is possible to reduce defects such as warpage of a substrate.

It is desirable that a capacitor according to the first embodiment be further provided with a first conductive layer provided in at least one first recess, a first dielectric layer interposed between the first conductive layer and a substrate, a second conductive layer provided in at least one second recess, and a second dielectric layer interposed between the second conductive layer and the substrate. This allows it to form a first capacitor element having a metal-insulator-metal (MIM) structure constituted by the first conductive layer, the first dielectric layer, and the substrate, and to form a second capacitor element having an MIM structure constituted by the second conductive layer, the second dielectric layer, and the substrate. In this case, the substrate may function as a conductor (interconnect) electrically coupling the first capacitor element and the second capacitor element to each other. As a result, a capacitor having a high withstand voltage can be achieved by stacking capacitors each provided with a first capacitor element and a second capacitor element along a thickness direction.

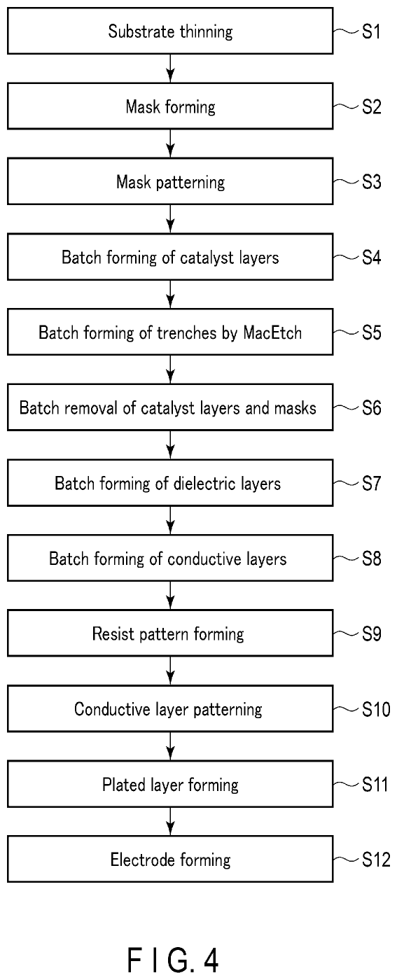

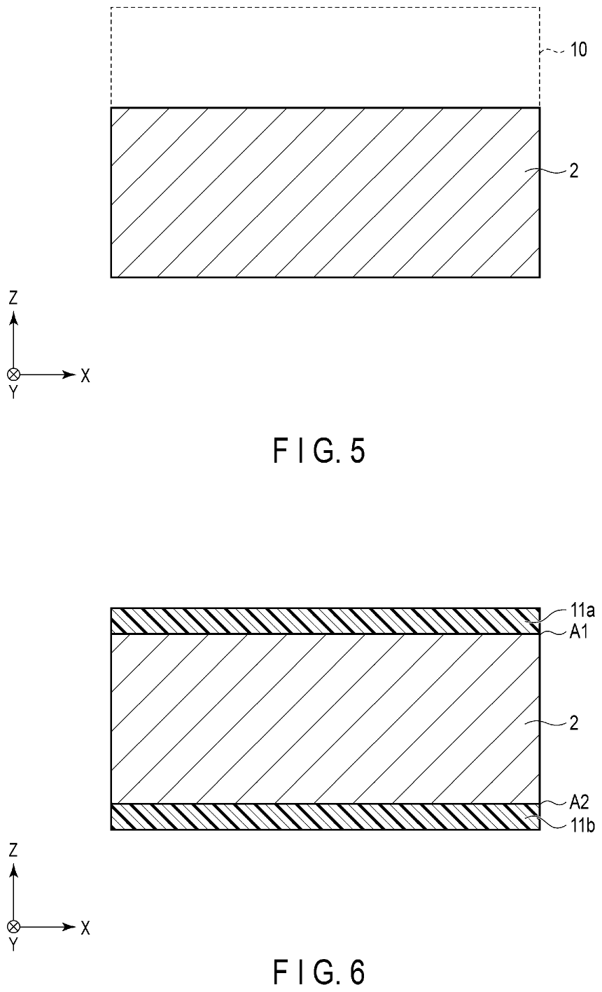

The capacitor of the first embodiment is manufactured by, for example, a method according to the first embodiment, which is shown in FIGS. 4 through 15. The method is hereinafter described with reference to FIGS. 4 through 15. In FIGS. 5 through 15, the X-axis direction is a first direction parallel to the main surface of the substrate 2, and the Y-axis direction is a second direction parallel to the main surface of the substrate 2 and perpendicular to the X-axis direction. The Z-axis direction is a thickness direction of the substrate 2, namely a direction perpendicular to the X-axis direction (first direction) and the Y-axis direction (second direction).

### (Step S1)

Step S1 is a substrate thinning step, an example of which is shown in FIG. 5. A substrate material 10 is thinned to a predetermined thickness by shaving, and a substrate 2 is thereby obtained. The thickness of the substrate 2 is 150 μm or smaller, as an example. Herein, the substrate 2 is a monocrystalline silicon wafer, as an example. A plane direction of the monocrystalline silicon wafer is not limited to a specific one; a silicon wafer having a (100) plane as one of the main surfaces is used in this example. As the substrate 10, a silicon wafer in which one of the main surfaces is a (110) surface may be used.

### (Step S2)

Step S2 is a mask forming step, an example of which is shown in FIG. 6. A mask layer 11a and a mask layer 11b are formed on the first main surface A1 and the second main surface A2 of the substrate 2, respectively. The mask layers 11a and 11b may be made from an organic material such as polyimide, fluororesin, phenol resin, acrylic resin, or novolac resin, or an inorganic material such as silicon oxide or silicon nitride. The mask layers 11a and 11b can be formed by, for example, existing semiconductor processes.

### (Step S3)

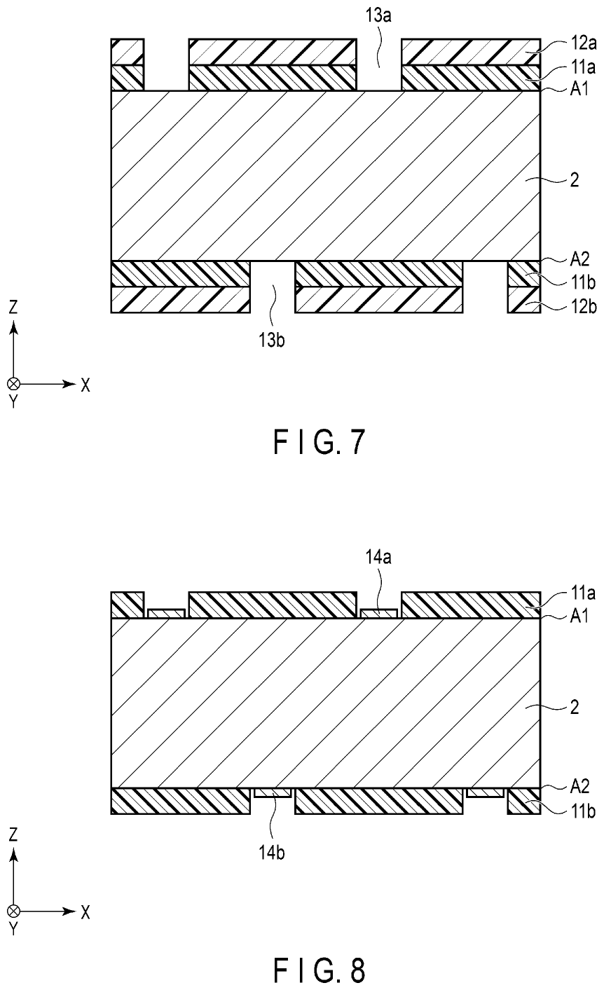

Step S3 is a patterning step, an example of which is shown in FIG. 7. Resist layers 12a and 12b are formed in a desired pattern on the mask layers 11a and 11b, respectively. The resist layers 12a and 12b may be made of a photo resist, for example. Next, the mask layers 11a and 11b are processed into a desired pattern by etching, such as reactive ion etching (RIE), so as to provide openings 13a and 13b in the mask layers 11a and 11b. Each opening 13a is provided at a position slated to become a first recess 5. Each opening 13b is provided at a position slated to become a second recess 6. Thereafter, the resist layers 12a and 12b are removed.

### (Step S4)

Step S4 is a step of forming catalyst layers on both surfaces of the substrate in a batch, an example of which is shown in FIG. 8. A first catalyst layer 14a is formed on an area of the first main surface A1 not covered by the mask layer 11a (including the openings 13a). Concurrently, a second catalyst layer 14b is formed on an area of the second main surface A2 not covered by the mask layer 11b (including the opening 13b).

By forming the first catalyst layer 14a on the first main surface A1 of the substrate 2 and forming the second catalyst layer 14b on the second main surface A2 of the substrate 2 in a batch, it is possible to reduce a difference between a stress applied to the first main surface A1 and a stress applied to the second main surface A2.

The first catalyst layer 14a and the second catalyst layer 14b are a discontinuous layer containing a noble metal. As an example, the first catalyst layer 14a and the second catalyst layer 14b may be a particulate layer formed of catalyst particles containing a noble metal.

The noble metal is, for example, one or more selected from the group consisting of gold, silver, platinum, rhodium, palladium, and ruthenium. The first catalyst layer 14a and the second catalyst layer 14b may further contain a metal other than a noble metal, such as titanium.

The first catalyst layer 14a and the second catalyst layer 14b can be formed by, for example, electroplating, reduction plating, or displacement plating. The first catalyst layer 14a and the second catalyst layer 14b may be formed by applying a dispersion containing the noble metal particles, or vapor phase deposition such as evaporation or sputtering. Of these methods, displacement plating is particularly favorable because it is possible to directly and evenly deposit the noble metal on the openings 13a and 13b of the mask layers 11a and 11b.

### (Step S5)

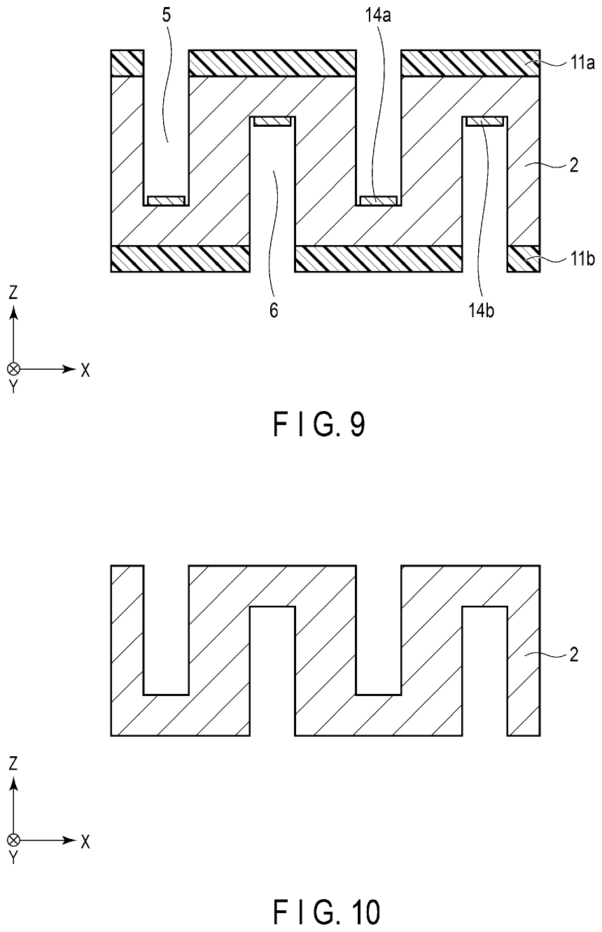

Step S5 is a step of forming recesses on both surfaces of the substrate in a batch by etching using a catalyst. As shown in the example of FIG. 9, trenches are formed on respective surfaces of the substrate in a batch by metal-assisted chemical etching (MacEtch).

With MacEtch, first trenches slated to be first recesses 5 and second trenches slated to be second recesses 6 on the substrate 2 can be formed by etching the substrate 2 under an effect of a catalyst comprising a noble metal.

Specifically, the substrate 2 is etched by an etchant. For example, a processing-target substrate including the substrate 2 is immersed in an etchant so as to bring the etchant into contact with the substrate 2.

The etchant may contain an oxidizer and hydrogen fluoride.

The concentration of hydrogen fluoride in the etchant is preferably in a range of 1 mol/L to 20 mol/L, more preferably in a range of 5 mol/L to 10 mol/L, further more preferably in a range of 3 mol/L to 7 mol/L. If the concentration of hydrogen fluoride is too low, it is difficult to achieve a high etching rate. If the concentration of hydrogen fluoride is too high, excessive side etching may occur.

The oxidizer can be at least one selected from, for example, hydrogen peroxide, nitric acid, AgNO₃, KAuCl₄, HAuCl₄, K₂PtCl₆, H₂PtCl₆, Fe(NO₃)₃, Ni(NO₃)₂, Mg(NO₃)₂, Na₂S₂O₈, K₂S₂O₈, KMnO₄ and K₂Cr₂O₇. Hydrogen peroxide is preferred as the oxidizing agent because it neither generates any harmful byproduct nor contaminates a semiconductor element.

The concentration of the oxidizer contained in the etchant is preferably in a range of 0.2 mol/L to 8 mol/L, more preferably in a range of 2 mol/L to 4 mol/L, further more preferably in a range of 3 mol/L to 4 mol/L.

The etchant may further contain a buffering agent. The buffering agent contains at least one of ammonium fluoride or aqueous ammonia, for example. According to one example, the buffering agent is ammonium fluoride. According to another example, the buffering agent is a mixture of ammonium fluoride and aqueous ammonia.

The etchant may further contain other components, such as water.

If such an etchant is used, the material of the substrate 2, silicon in this example, is oxidized only in the area in the vicinity of the first catalyst layer 14a or the second catalyst layer 14b. The resultant oxide is dissolved and removed by a hydrofluoric acid. For this reason, only the area in the vicinity of the first catalyst layer 14a or the second catalyst layer 14b is selectively etched.

The first catalyst layer 14a moves toward the second main surface along the Z-axis direction as the etching proceeds, and the etching is performed in that area in the above-described manner. As a result, as shown in FIG. 9, at the position of the first catalyst layer 14a, etching proceeds in the Z-axis direction, which is perpendicular to the first main surface, from the first main surface to the second main surface.

The second catalyst layer 14b, on the other hand, moves toward the first main surface as the etching proceeds, and the etching is performed in that area in the above-described manner. As a result, as shown in FIG. 9, at the position of the second catalyst layer 14b, etching proceeds in the Z-axis direction, which is perpendicular to the second main surface, from the second main surface to the first main surface.

Thus, as shown in FIG. 9, the recesses corresponding to the first recesses 5 and the recesses corresponding to the second recesses 6 are formed at the same time on the first main surface A1 and the second main surface A2, respectively. It is thus possible to reduce a difference between a stress applied to the first main surface A1 and a stress applied to the second main surface A2.

### (Step S6)

Step S6 is a process of removing the catalyst layers and the masks on both surfaces in a batch, an example of which is shown in FIG. 10. Aqua regia can be used to remove the catalyst layers, for example. A hot phosphoric acid may be used to remove the mask layers.

By removing the catalyst layers and the masks in both surfaces in a batch, it is possible to reduce a difference between a stress applied to the first main surface A1 and a stress applied to the second main surface A2.

### (Step S7)

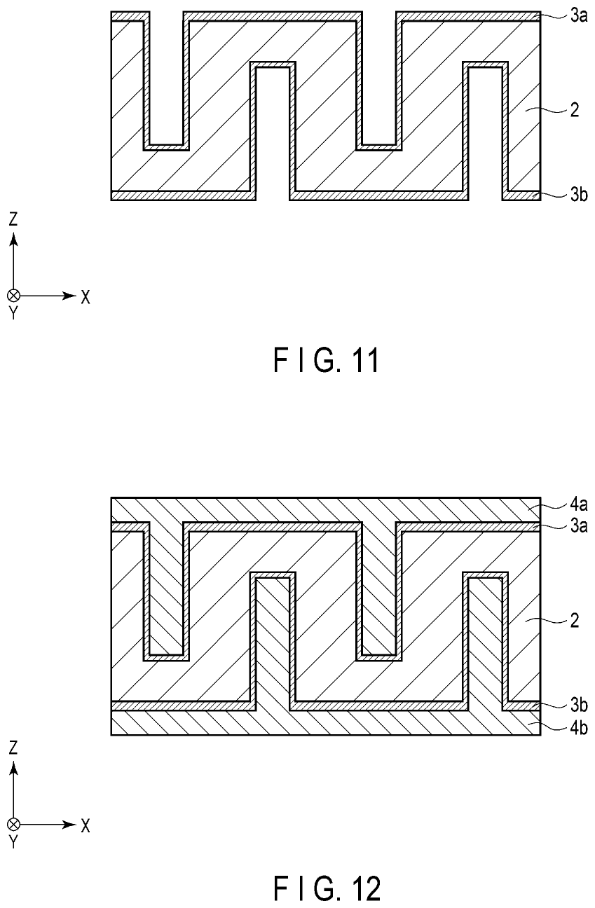

Step S7 is a step of forming dielectric layers on both surfaces of the substrate in a batch. As shown in the example of FIG. 11, a first dielectric layer 3a is provided on the first main surface A1 of the substrate 2 and the inner surface of each of the first recesses 5. At this time, a second dielectric layer 3b is provided on the second main surface A2 of the substrate 2 and the inner surface of each of the second recesses 6. The first dielectric layer 3a and the second dielectric layer 3b can be formed by low pressure chemical vapor deposition (LPCVD) or thermal oxidization on the surface of the substrate 2.

By forming the first and second dielectric layers 3a and 3b on the surfaces of the substrate 2 at the same time, it is possible to reduce a difference between a stress applied to the first main surface A1 and a stress applied to the second main surface A2 of the substrate 2.

### (Step S8)

Step S8 is a step of forming conductive layers on both surfaces of the substrate in a batch. As shown in the example of FIG. 12, a first conductive layer 4a is formed on the first dielectric layer 3a on the first main surface A1 of the substrate 2 and on the first dielectric layer 3a formed on the inner surface of each of the first recesses 5. At this time, a second conductive layer 4b is formed on the second dielectric layer 3b of the second main surface A2 of the substrate 2 and on the second dielectric layer 3b formed on the inner surface of each of the second recesses 6. The first and second conductive layers 4a and 4b made of polysilicon doped with impurities may be formed by LPCVD, for example. The first and second conductive layers 4a and 4b made of a metal can be formed by, for example, electroplating, reduction plating, or displacement plating.

By forming the first and second conductive layers 4a and 4b in a batch on the first main surface A1 including the first recesses 5 and the second main surface A2 including the second recesses 6, respectively, the first and second conductive layers 4a and 4b having the same film thickness can be respectively formed on the surfaces at the same time. It is thus possible to reduce a difference between a stress applied to the first main surface A1 and a stress applied to the second main surface A2.

### (Step S9)

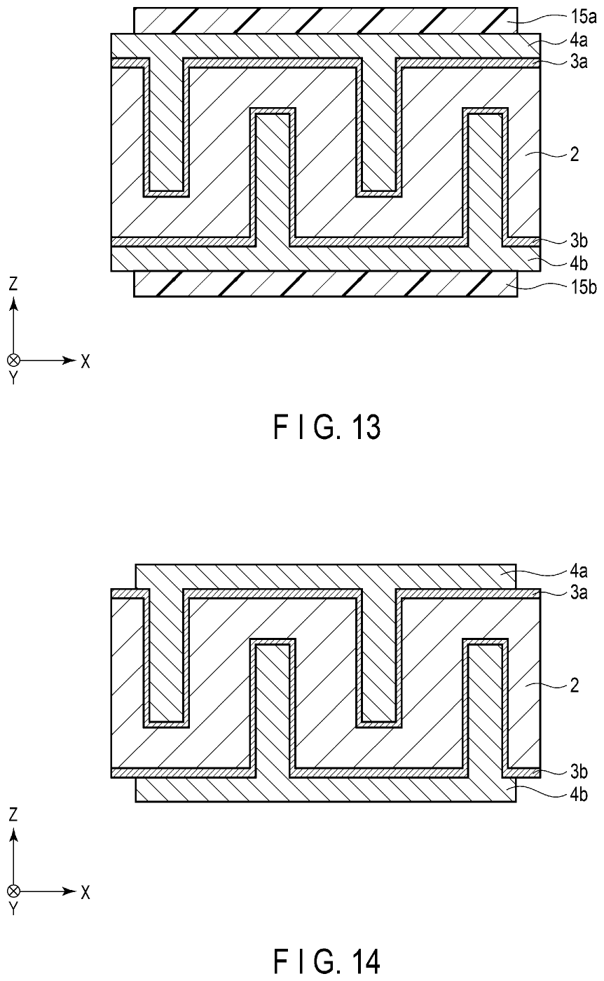

Step S9 is a step of forming a resist pattern. As shown in FIG. 13, for example, resist layers 15a and 15b are formed in a desired pattern on the first and second mask layers 4a and 4b, respectively. The resist layers 15a and 15b may be made of a photo resist, for example. One of the resist layers 15a and 15b may be formed after the other, or both of the resist layers 15a and 15b may be formed at the same time.

### (Step S10)

Step S10 is a step of patterning conductive layers. As shown in FIG. 14, for example, the first and second conductive layers 4a and 4b are processed into a desired pattern by etching, for example chemical dry etching (CDE). One of the conductive layers may be etched after the other, or both of the conductive layers may be etched at the same time. After the etching, the resist layers 15a and 15b may be removed, as needed.

### (Step S11)

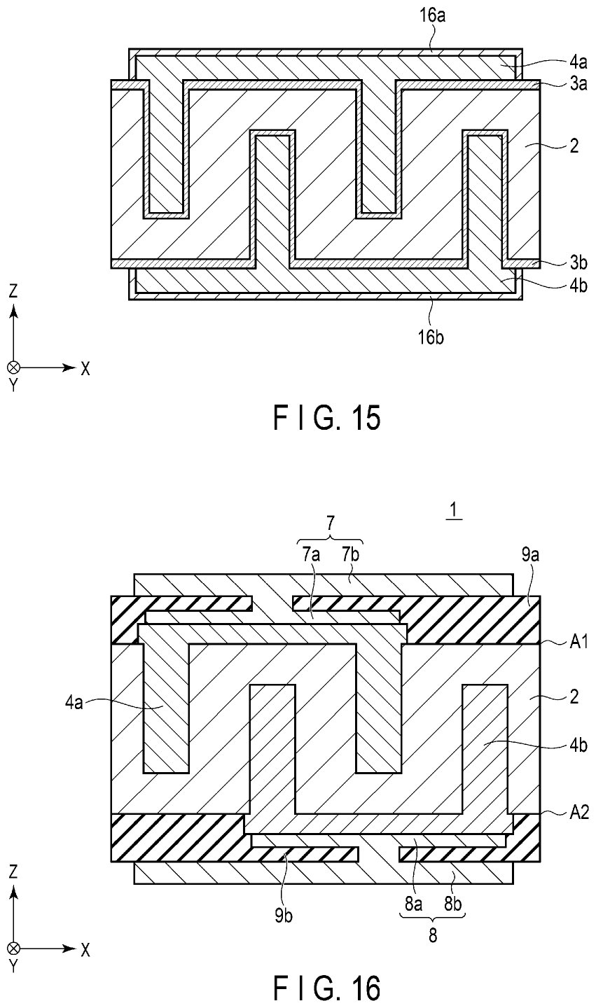

Step S11 is a step of forming plated layers. As shown in FIG. 15, for example, the plated layer 16a covers the surface of the first conductive layer 4a along the XY plane and the edge surfaces continuous to this surface. The plated layer 16b covers the surface of the second conductive layer 4b along the XY plane and the edge surfaces continuous to this surface. The plated layers 16a and 16b may be made of nickel (Ni), aluminum (Al), or a NiAl alloy, for example. One of the plated layers 16a and 16b may be formed after the other, or both of the plated layers 16a and 16b may be formed at the same time.

The formation of the plated layers may be omitted.

### (Step S12)

Step S12 is a step of forming electrodes. An electrode may be an aluminum electrode, for example. The electrode may be formed by a conformal deposition, such as sputtering deposition. One of the electrodes may be formed after the other, or both of the electrodes may be formed at the same time. The electrodes may be formed on the plated layers or directly on the conductive layers without the plated layers being interposed therebetween.

If the conductive layers are used as electrodes, step S12 can be omitted.

The method of manufacturing a capacitor according to the first embodiment may include all steps S1 through S12; however, some of the steps, for example step S11 or step S12, may be omitted.

In the manufacturing method of a capacitor according to the first embodiment, the process from step S4 through step S8 is performed on respective surfaces of a substrate in a batch. In other words, after the step of forming first recesses on a first main surface of a substrate and the step of forming second recesses on a second main surface are performed in a batch, dielectric layers are respectively formed on the first main surface and the second main surface in a batch, and thereafter conductive layers are respectively formed on the first main surface and the second main surface in a batch. As a result, it is possible to reduce a difference between a stress applied to the first main surface and a stress applied to the second main surface. It is possible to form layers having the same thickness on the first main surface and the second main surface of the substrate at the same time. With this method, defects such as warpage and cracks in a substrate can be reduced. Furthermore, the batch process leads to a reduction in the number of steps.

In the first embodiment, first recesses and second recesses are formed by etching using a catalyst, such as MacEtch; if the recesses are formed by dry etching, on the other hand, the process has to be a consecutive process. For example, after the first recesses are formed on the first main surface and conductive layers are formed thereon, the substrate is thinned to the thickness corresponding to the depth of the first recess, and the second recesses are similarly formed on the second main surface and conductive layers are formed thereon. This process requires handling of a thin substrate. Furthermore, in this process, warpage occurs in the substrate when the conductive layers are formed. To address these issues, in the first embodiment, first recesses and second recesses are formed on both surfaces of a substrate in a batch by MacEtch and conductive layers may be formed in a batch thereafter. It is thus possible to reduce the chances of a thin substrate needing to be handled and to suppress warpage when the conductive layers are formed.

### Second Embodiment

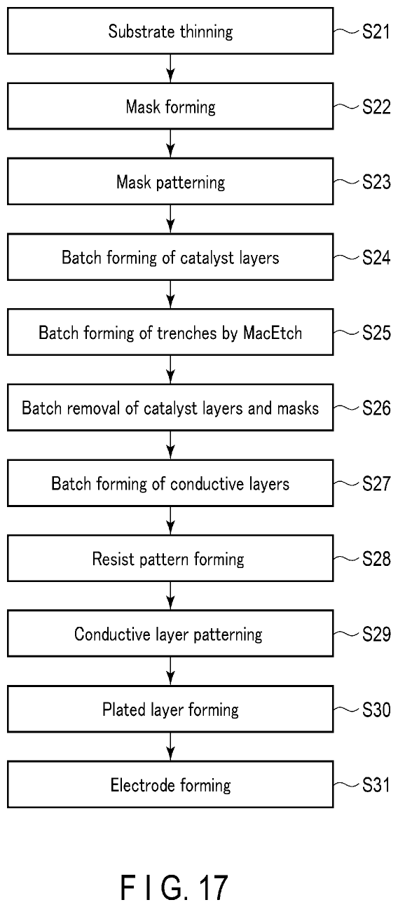

A capacitor of the second embodiment and a method of manufacturing the capacitor are shown in FIGS. 16 and 17. FIG. 16 is a sectional view of a capacitor of the second embodiment, viewed in the thickness direction (Z-axis direction). FIG. 17 is a flowchart showing an example of a manufacturing method of the capacitor according to the second embodiment. The components that have been described with reference to FIGS. 1 through 15 are referred to by the same symbols and explanations of these components are omitted.

In the capacitor of the second embodiment, the substrate 2 is an intrinsic semiconductor substrate, and the structure is the same as the capacitor 1 shown in FIGS. 1 through 3 except that no dielectric layers are provided. The intrinsic semiconductor substrate may be a silicon wafer having a resistance rate of 10 kΩcm or greater, for example. On the first main surface A1 and the second main surface A2 of the substrate 2, the first recesses 5 and the second recesses 6 are alternately aligned in the X-axis direction (first direction), separated from one another by side walls, similarly to the first embodiment. On the inner surfaces of the first recesses 5 and the second recesses 6, the first and second conductive layers 4a and 4b are directly provided, without the dielectric layer. The first and second conductive layers 4a and 4b are comb-shaped. The first and second conductive layers 4a and 4b are also formed on the first main surface A1 and the second main surface A2 in addition to the inner surfaces of the first recesses 5 and the second recesses 6. The first conductive layer 4a is provided on the first main surface A1 located between adjacent first recesses 5 between which the side wall is interposed in the X-axis direction (first direction). The first conductive layers 4a provided inside each of the first recesses 5 are thus electrically coupled to each other. The second conductive layer 4b is provided on the second main surface A2 located between adjacent second recesses 6 with the side wall interposed therebetween in the X-axis direction (first direction). The second conductive layers 4b provided inside each of the second recesses 6 are thus electrically coupled to each other. The details of the first electrode 7, the second electrode 8, and the insulating layers 9a and 9b are as described in the first embodiment.

According to the second embodiment, the capacitor includes at least one first recess provided on the first main surface of the substrate along one direction and at least one second recess provided on the second main surface of the substrate along said one direction. In the substrate, at least one first recess and at least one second recess are alternately aligned along said one direction. According to a capacitor having this substrate, it is possible to reduce defects, such as warpage and cracks in the substrate, through processing the first main surface and the second main surface in a batch. Furthermore, batch processing of the surfaces leads to a reduction in the number of steps. Furthermore, defects of a substrate can be reduced even by using as a conductive layer polysilicon having a low resistance rate but a large stress; therefore, it is possible to reduce defects of a substrate regardless of a type of conductive layer.

It is desirable if the capacitor of the second embodiment further includes a first conductive layer provided in at least a part of the inner surfaces of the first recesses and a second conductive layer provided in at least a part of the inner surfaces of the second recesses. It is thus possible to form a capacitor element having an MIM structure from the first conductive layer, the substrate, and the second conductive layers.

FIG. 17 shows a flowchart of an example of a method of manufacturing a capacitor of the second embodiment, which was described with reference to FIG. 16. This manufacturing method includes substrate thinning (S21), mask forming (S22), mask patterning (S23), batch forming of catalyst layers (S24), batch forming of trenches by MacEtch (S25), batch removal of catalyst layers and masks (S26), batch forming of conductive layers (first and second conductive layers) (S27), resist pattern forming (S28), conductive layer (first and second conductive layers) patterning (S29), plated layer forming (S30), and electrode forming (S31). The method is the same as that of the first embodiment, except that step S27 of batch forming conductive layers after step S26 of batch removal of catalyst layers and masks is performed, without forming dielectric layers. The manufacturing method of a capacitor according to the second embodiment may include all of steps S21 through S31; however, step S30 or step S31 may be omitted, or some of the steps may be omitted.

In the manufacturing method of a capacitor according to the second embodiment, the process from step S24 through step S28 is performed on both surfaces of a substrate in a batch. In other words, after the step of forming first recesses on a first main surface of a substrate and the step of forming second recesses on a second main surface are performed in a batch, conductive layers are respectively formed on the first main surface and the second main surface in a batch. As a result, it is possible to reduce a difference between a stress applied to the first main surface and a stress applied to the second main surface. It is possible to form layers having the same thickness on the first main surface and the second main surface of the substrate at the same time. With this method, defects such as warpage and cracks in a substrate can be reduced. Furthermore, the batch process leads to a reduction in the number of steps.

By forming the conductive layers in a batch after the first recesses and the second recesses are formed in a batch by etching using a catalyst, such as MacEtch, it is possible to reduce the chances of a thin substrate needing to be handled and to suppress warpage when the conductive layers are formed.

### Third Embodiment

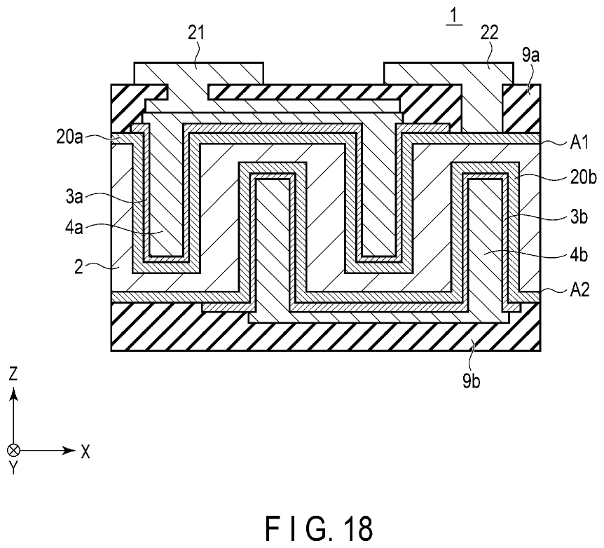

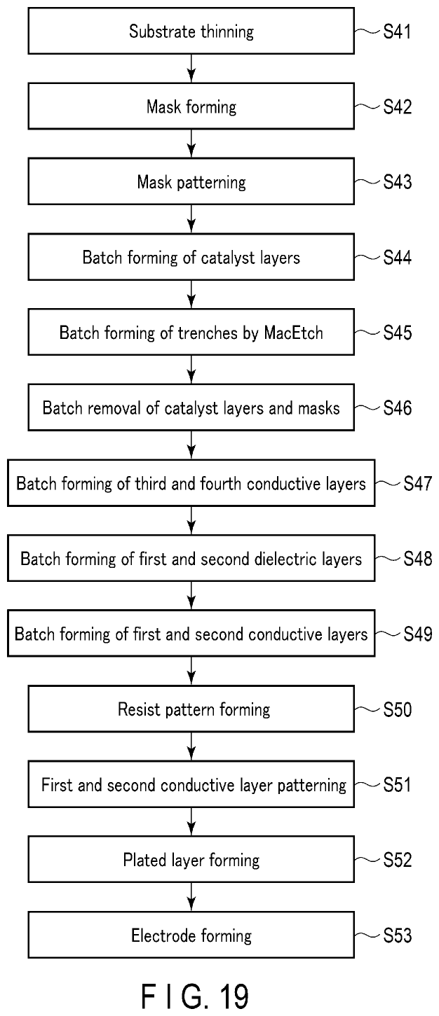

A capacitor of the third embodiment and a method of manufacturing the capacitor are shown in FIGS. 18 and 19. FIG. 18 is a sectional view of a capacitor of the third embodiment, viewed in the thickness direction (Z-axis direction). FIG. 19 is a flowchart showing an example of a manufacturing method of the capacitor according to the third embodiment. The components that have been described with reference to FIGS. 1 through 15 are referred to by the same symbols and explanations of these components are omitted.

As shown in FIG. 18, the capacitor 1 of the third embodiment includes a substrate 2, a first dielectric layer 3a, a second dielectric layer 3b, a first conductive layer 4a, a second conductive layer 4b, a third conductive layer 20a, a fourth conductive layer 20b, a third electrode 21, a fourth electrode 22, and insulating layers 9a and 9b.

In FIG. 18, the X-axis direction is a first direction parallel to the main surface of the substrate 2, and the Y-axis direction is a second direction parallel to the main surface of the substrate 2 and perpendicular to the X-axis direction. The Z-axis direction is a thickness direction of the substrate 2, namely a direction perpendicular to the X-axis direction (first direction) and the Y-axis direction (second direction).

A substrate similar to the one described in the first embodiment is used as the substrate 2. The first recesses 5 and the second recesses 6 are provided on the first main surface A1 and the second main surface A2 in a manner similar to the one described with reference to FIGS. 2 and 3. The first recesses 5 and the second recesses 6 are alternately aligned in the substrate 2 along the X-axis direction (first direction), spaced apart from one another by side walls. The details of the first recesses 5 and the second recesses 6 are as described in the first embodiment.

The details of the first and second dielectric layers 3a and 3b and the first and second conductive layers 4a and 4b are as described in the first embodiment.

The third conductive layer 20a is provided in the inner surfaces of the first recesses 5 and on the first surface A1. The first dielectric layer 3a is interposed between the third conductive layer 20a and the comb-shaped first conductive layer 4a. The fourth conductive layer 20b is provided on the inner surfaces of the second recesses 6 and the second main surface A2. The second dielectric layer 3b is interposed between the fourth conductive layer 20b and the comb-shaped second conductive layer 4b. If the substrate 2 is a semiconductor substrate such as a silicon substrate, the third conductive layer 20a and the fourth conductive layer 20b may be a doping layer provided in a surface region of the semiconductor substrate, and the surface region is doped with impurities. Examples of impurities are P-type impurities and N-type impurities. The third conductive layer 20a and the fourth conductive layer 20b may be made of a metal or an alloy of molybdenum, aluminum, gold, tungsten, platinum, nickel, or copper. The third and fourth conductive layers 20a and 20b may have a single-layer structure or a multi-layer structure.

The insulating layer 9a insulates the third electrode 21 and the fourth electrode 22 from each other. Each of the third electrode 21 and the fourth electrode 22 projects from the surface of the insulating layer 9a along the XY plane in the same direction along the Z-axis direction (the thickness direction of the substrate 2). The insulating layer 9a has one or more through-holes. In one through-hole of the insulating layer 9a, the third electrode 21 is electrically coupled to the first conductive layer 4a. In another through-hole of the insulating layer 9a, the fourth electrode 22 is electrically coupled to the third conductive layer 20a. The insulating layer 9a covers the edges of the first conductive layer 4a and the first dielectric layer 3a, and the third conductive layer 20a.

The insulating layer 9b covers the second conductive layer 4b, the second dielectric layer 3b, and the fourth conductive layer 20b, and externally insulates these layers.

The insulating layers 9a and 9b are made of an inter-layer insulating film, such as tetraethoxysilane (TEOS), for example.

The third electrode 21 and the fourth electrode 22 can be obtained by deposition of a metal, such as aluminum, by sputtering, for example.

This capacitor 1 may further include a plated layer (not shown). The plated layer may be made of nickel (Ni), aluminum (Al), or a NiAl alloy, for example. The plated layer may be provided on a conductive layer (for example, the first conductive layer 4a, the second conductive layer 4b, the third conductive layer 20a, or the fourth conductive layer 20b).

In a capacitor having the above-described structure, the substrate 2 interposed between the third and fourth conductive layers 20a and 20b and the first conductive layer 4a constitutes a capacitor element having an MIM structure, with the first dielectric layer 3a interposed therebetween, and constitutes a capacitor element having an MIM structure in conjunction with the second conductive layer 4b, with the second dielectric layer 3b interposed therebetween.

According to the third embodiment, the capacitor includes at least one first recess provided on the first main surface of the substrate along one direction and at least one second recess provided on the second main surface of the substrate along said one direction. In the substrate, at least one first recess and at least one second recess are alternately aligned along said one direction. According to a capacitor having this substrate, it is possible to reduce defects, such as warpage and cracks in the substrate, through processing the first main surface and the second main surface in a batch. Furthermore, batch processing of the surfaces leads to a reduction in the number of steps. Furthermore, defects of a substrate can be reduced even by using as a conductive layer polysilicon having a low resistance rate but a large stress; therefore, it is possible to reduce defects of a substrate regardless of a type of conductive layer.

The capacitor manufacturing method of the third embodiment, which was described with reference to FIG. 18, is explained. This manufacturing method includes substrate thinning (S41), mask forming (S42), mask patterning (S43), batch forming of catalyst layers (S44), batch forming of trenches by MacEtch (S45), batch removal of catalyst layers and masks (S46), batch forming of conductive layers (third and fourth conductive layers) (S47), batch forming of dielectric layers (first and second dielectric layers) (S48), batch forming of conductive layers (first and second conductive layers) (S49), resist pattern forming (S50), conductive layer (first and second conductive layer) patterning (S51), plated layer forming (S52), and electrode forming (S53). This manufacturing method is performed similarly to the method of the first embodiment, except that step S47 of batch forming the third and fourth conductive layers is performed after step S46 of batch removal of the catalyst layers and masks, and step S48 of batch forming the first and second dielectric layers is successively performed. The manufacturing method of a capacitor according to the third embodiment may include all of steps S41 through S53; however, step S52 or step S53 may be omitted, or some of the steps may be omitted.

Hereinafter, the details of step S47 of forming the third and fourth conductive layers in a batch on the surfaces are described.

After step S46 of batch removal of the catalyst layers and masks in a manner similar to step S6 of the first embodiment, a target portion in each of the first main surface A1, the inner surfaces of the first recesses 5, the second main surface A2, and the inner surfaces of the second recesses 6 are doped with impurities or a metal layer or an alloy layer is provided in the target portion. The method of forming a doped layer doped with impurities is not limited to a particular method, and CVD, LPCVD, or ion injection, etc. may be adopted. The metal layer and the alloy layer can be deposited by sputtering.

Step S48 (batch forming of the first and second dielectric layers) is performed in a manner similar to step S7. Step S49 (batch forming of the first and second conductive layers) is performed in a manner similar to step S8.

In the manufacturing method of a capacitor according to the third embodiment, the process from step S44 through step S48 is performed on both surfaces of a substrate in a batch. In other words, after the step of forming first recesses on a first main surface of a substrate and the step of forming second recesses on a second main surface are performed in a batch, third and fourth conductive layers are successively formed on the first main surface and the second main surface respectively in a batch, and first and second dielectric layers are successively formed in a batch, and first and second conductive layers are successively formed in a batch. As a result, it is possible to reduce a difference between a stress applied to the first main surface and a stress applied to the second main surface. It is possible to form layers having the same thickness on the first main surface and the second main surface of the substrate at the same time. With this method, defects such as warpage and cracks in a substrate can be reduced. Furthermore, the batch process leads to a reduction in the number of steps.

By forming the conductive layers and the dielectric layers in a batch after the first recesses and the second recesses are formed in a batch by etching using a catalyst, such as MacEtch, it is possible to reduce the chances of a thin substrate needing to be handled and to suppress warpage when the conductive layers and the dielectric layers are formed.

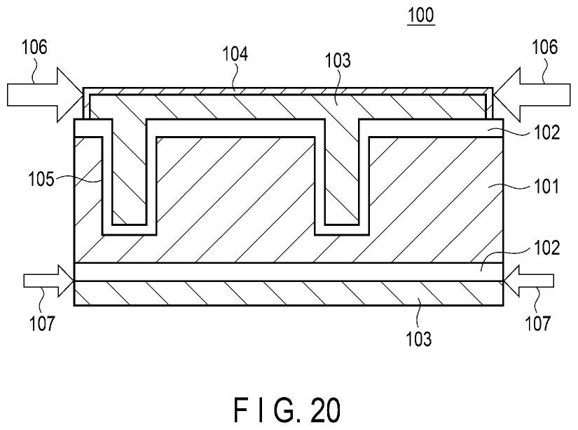

A capacitor of a comparative example has the structure shown in FIG. 20. The capacitor 100 shown in FIG. 20 includes a substrate 101, a dielectric layer 102, a conductive layer 103, and an aluminum (Al) electrode 104. Trenches 105 are formed on one surface of the substrate 101 in a comb-like manner. The dielectric layer 102 is provided on one surface of the substrate 101, the inner surface of the trenches 105, and the other surface of the substrate 101. The conductive layer 103 is provided on the dielectric layer 102, and a part of the conductive layer 103 is embedded in the trenches 105. The A1 electrode 104 is formed on the conductive layer 103 provided on one surface of the substrate 101. In the manufacturing of the capacitor 100 having such a structure, a difference in stress between one surface and the other surface of the substrate 101 becomes great when the conductive layer 103 is provided. Specifically, the stress 106 applied to the side on which the trenches 105 of the substrate 101 are formed becomes greater than the stress 107 on the opposite side of the substrate 101. As a result, the substrate 101 is easily warped. Warpage of the substrate 101 causes defects, such as cracks in the substrate 101.

If polysilicon is used as the conductive layer 103, for example, the stress of the conductive layer 103 can be lowered by increasing the deposition temperature as a method of mitigating the difference in stress between one surface and the other surface of the substrate 101. However, if the stress of the conductive layer 103 is reduced, the resistance rate (mΩ·cm) of the conductive layer 103 becomes greater. Thus, there is a tradeoff relationship between the electric characteristics of a capacitor and warpage of a substrate.

According to a capacitor and a manufacturing method thereof according to the first through third embodiments, defects, such as warpage and cracks in a substrate, can be reduced without sacrificing electric characteristics of the capacitor.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A capacitor comprising:
a substrate having a first main surface and a second main surface;
at least one first recess provided along one direction on the first main surface of the substrate; and
at least one second recess provided along said one direction on the second main surface of the substrate;
wherein the at least one first recess and the at least one second recess are alternately aligned along said one direction.

2. The capacitor of claim 1 further comprising:
a first conductive layer provided in the at least one first recess;
a first dielectric layer interposed between the first conductive layer and the substrate;
a second conductive layer provided in the at least one second recess; and
a second dielectric layer interposed between the second conductive layer and the substrate.

3. The capacitor of claim 2 further comprising:
a third conductive layer interposed between the first dielectric layer and the substrate; and
a fourth conductive layer interposed between the second dielectric layer and the substrate.

4. The capacitor of claim 2, wherein
the first conductive layer and the second conductive layer are made of polysilicon doped with impurities.

5. The capacitor of claim 1, wherein
the substrate is an intrinsic semiconductor substrate having a resistance rate of 10 KΩcm or greater.

6. A method of manufacturing the capacitor of claim 1, the method comprising:
forming the at least one first recess and the at least one second recess of the substrate in a batch by etching using a catalyst.

7. The capacitor manufacturing method of claim 6 further comprising:
performing a step of forming a first conductive layer in the at least one first recess of the substrate and a step of forming a second conductive layer in the at least one second recess in a batch.

8. The capacitor manufacturing method of claim 7, wherein
before the first conductive layer and the second conductive layer are formed in a batch, forming a first dielectric layer in an inner surface of the at least one first recess of the substrate and forming a second dielectric layer in an inner surface of the at least one second recess are performed in a batch.
